(19) United States
(12) Patent Application Publication
(10) Pub. No.: US 2025/0157901 A1
(43) Pub. Date: May 15, 2025

(54) ELECTRONIC DEVICE AND MANUFACTURING METHOD THEREOF

(71) Applicant: InnoLux Corporation, Miao-Li County (TW)

(72) Inventors: Yan-Tang DAI, Miao-Li County (TW); Tzu-Min YAN, Miao-Li County (TW)

(21) Appl. No.: 18/910,695

(22) Filed: Oct. 9, 2024

(30) Foreign Application Priority Data
Nov. 9, 2023 (CN) 202311485736.8

(51) Int. Cl. H01L 23/498; H01L 21/02; H01L 25/16; H01L 29/06

(52) U.S. Cl. CPC H01L 23/49811; H01L 21/02354; H01L 23/49844; H10D 62/117; H01L 25/167

(57) ABSTRACT

An electronic device includes a first substrate, a first wire disposed on a first surface of the first substrate, a second wire disposed on the second surface of the first substrate, and a side wire disposed on a side surface, a chamfer surface and the second surface of the first substrate and electrically connected to the first wire and the second wire. The second surface is opposite the first surface, the side surface is between the first surface and the second surface, and the chamfer surface is between the second surface and the side surface. The side wire has a first portion on the side surface, a second portion on the chamfer surface, and a third portion on the second surface. The width of the second portion is less than or equal to the width of the second wire.

### CROSS REFERENCE TO RELATED APPLICATIONS

This application claims priority of China Patent Application No. 202311485736.8, filed on Nov. 9, 2023, the entirety of which is incorporated by reference herein.

### BACKGROUND OF THE INVENTION

### Field of the Invention

The present disclosure relates to an electronic device, and in particular, to an electronic device including a side wire.

### Description of the Related Art

With the developments being made in digital technology, electronic devices have become widely used in in daily life. A seamless electronic device can provide users with a better user experience.

Seamless electronic devices are currently being prepared by forming a side wire on the side surface of an electronic device. However, the side wire located at a corner of the electronic device has problems, such as high contact resistance, and it is prone to breakage and damage.

### BRIEF SUMMARY OF THE INVENTION

In view of the above problems, the present disclosure provides an electronic device including a side wire having an improved structure.

An embodiment of the present disclosure provides an electronic device. The electronic device includes a first substrate, a first wire, a side wire, and a second wire. The first substrate has a first surface, a second surface opposite the first surface, a side surface between the first surface and the second surface, and a chamfer surface between the second surface and the side surface. The first wire is disposed on the first surface of the first substrate. The second wire is disposed on the second surface of the first substrate. The side wire is disposed on the side surface, the chamfer surface and the second surface of the first substrate and is electrically connected to the first wire and the second wire. The side wire has a first portion on the side surface, a second portion on the chamfer surface, and a third portion on the second surface, wherein the width W2 of the second portion is less than or equal to the width W3 of the second wire.

An embodiment of the present disclosure provides a manufacturing method of an electronic device. The manufacturing method of the electronic device includes: providing a first substrate, the first substrate having a first surface, a second surface opposite the first surface, a side surface between the first surface and the second surface, and a chamfer surface between the second surface and the side surface; forming a first wire on the first surface; forming a second wire on the second surface; forming a conductive layer on the side surface, the chamfer surface and the second surface; patterning the conductive layer to form a side wire, and the side wire is electrically connected to the first wire and the second wire, wherein a first portion of the side wire on the side surface has a first width W1, a second portion of the side wire on the chamfer surface has a second width W2, the second wire has a third width W3, and the second width W2 is less than or equal to the third width W3.

### BRIEF DESCRIPTION OF THE DRAWINGS

The present disclosure can be more fully understood from the following detailed description when read in conjunction with the accompanying drawings. It should be noted that, in accordance with the standard practice in the industry, various features are not drawn to scale. In fact, the dimensions of the various features may be arbitrarily increased or reduced for clarity of discussion.

FIG. 1 is a cross-sectional schematic view of an electronic device according to an embodiment of the present disclosure.

FIG. 2 is an enlarged schematic view of an area A of the electronic device shown in FIG. 1.

FIG. 3 is a schematic plan view of the area A of the electronic device shown in FIG. 1.

FIG. 4 is a cross-sectional schematic view of an electronic device according to an embodiment of the present disclosure.

FIG. 5 is a cross-sectional schematic view of an electronic device according to an embodiment of the present disclosure.

FIG. 6 is a flowchart of a manufacturing method of an electronic device according to an embodiment of the present disclosure.

FIGS. 7A to 7C are partial schematic plan views of an electronic device during a step of patterning a conductive layer in the manufacturing method of the electronic device according to an embodiment of the present disclosure.

FIGS. 8A to 8C are partial schematic plan views of an electronic device during steps of patterning a conductive layer in the manufacturing method of the electronic device according to an embodiment of the present disclosure.

FIGS. 9A to 9D are partial schematic plan views of an electronic device during steps of patterning a conductive layer in the manufacturing method of the electronic device according to an embodiment of the present disclosure.

FIGS. 10A to 10C are partial schematic plan views of an electronic device during steps of patterning a conductive layer in the manufacturing method of the electronic device according to an embodiment of the present disclosure.

FIGS. 11A to 11C are partial schematic plan views of an electronic device during steps of patterning a conductive layer in the manufacturing method of the electronic device according to an embodiment of the present disclosure.

### DETAILED DESCRIPTION OF THE INVENTION

The electronic device according to an embodiment of the present disclosure will be described in detail below. It should be understood that the following description provides many different embodiments for implementing different aspects of some embodiments of the present disclosure. The specific components and arrangements described below are only used to briefly and clearly describe some embodiments of the present disclosure. Of course, these are only intended to illustrate and are not intended to be limiting. In addition, similar and/or corresponding reference numerals may be used to identify similar and/or corresponding elements in different embodiments to clearly describe the present disclosure. However, use of these similar and/or corresponding reference numerals is only for the purpose of simply and clearly describing some embodiments of the present disclosure, and does not imply any correlation between the different embodiments and/or structures discussed.

It should be appreciated that embodiments may use spatially relative terms, such as “lower” or “bottom” or “higher” or “top” to describe one element's relationship to another element(s) in the viewings. It is to be understood that if the device in the view is turned so that the top and bottom are reversed, an element described on a ‘lower’ side will become an element on a ‘higher’ side. The embodiments of the present disclosure may be understood in conjunction with the drawings, and the drawings of the present disclosure are considered part of the description of the disclosure. It should be understood that the drawings of the present disclosure are not drawn to scale and indeed the size of the elements may be arbitrarily enlarged or reduced in order to clearly show the features of the present disclosure.

Furthermore, when it is stated that a first material layer is on or above a second material layer, it may include a situation in which the first material layer is in direct contact with the second material layer, or a situation in which the first material layer may not be in direct contact with the second material layer, i.e., the first material layer may be separated from the second material layer by one or more other material layers. However, when it is stated that the first material layer is directly on the second material layer, it means that the first material layer is in direct contact with the second material layer.

In addition, it should be understood that ordinal numbers used in the specification and claims, such as “first”, “second”, etc., are used to modify elements. The ordinal numbers do not imply or represent numbers of the element (or elements). The ordinal numbers do not represent the order of one element over another or the order of manufacturing method. The ordinal numbers are only used to clearly distinguish two elements having the same name. The claims and the specification may not use the same terms. Therefore, the first element in the specification may be the second component in the claim.

In some embodiments of the present disclosure, unless otherwise defined, terms related to joining and connecting, such as “connection”, “interconnection”, etc., may mean that two structures are in direct contact, or may also mean that the two structures are not in direct contact and other structures are between the two structures. The terms related to joining and connecting may also include the situation where both structures are movable or both structures are fixed. In addition, the term “electrically connected” or “coupled” includes any direct or indirect means of electrical connection.

In the disclosure, the terms “about” and “substantially” usually indicates a value of a given value or range that varies within 10%, within 5%, or within 3%, or within 2%, or within 1%, or within 0.5%. The quantities given herein are approximate quantities, i.e. the meaning of “about” and “substantially” may be implied in the absence of a specific description of “about” and “substantially”. The term “a range between a first value and a second value” means that the range includes the first value, the second value, and other values in between.

It should be understood that the following embodiments may be used to replace, reorganize or combine features of several different embodiments to complete other embodiments without departing from the spirit of the present disclosure. As long as the features of the various embodiments do not violate the spirit of the disclosure or conflict with each other, they can be combined and used arbitrarily.

Unless otherwise defined, all terms (including technical and scientific terms) used herein have the same meaning as commonly understood by a person skilled in the art to which the disclosure pertains. It will be further understood that terms, such as those defined in commonly used dictionaries, should be interpreted as having a meaning consistent with the relevant technology and the context or background of this disclosure and will not be interpreted in an idealized or overly formal sense unless expressly so defined herein.

The electronic device may include a display device, an antenna device, a sensing device, a touch electronic device (touch display), a packaging device, a curved electronic device (curved display) or a non-rectangular electronic device (free shape display), but is not limited thereto. The electronic device may be a bendable or flexible electronic device. The antenna device may be a liquid crystal type antenna, but is not limited thereto. The antenna device may include an antenna splicing device, but is not limited thereto. The packaging device may be suitable for use in a Wafer Level Package (WLP) technology or Panel Level Package (PLP) technology, such as a packaging device in a Chip First process or Chip Last (RDL First) process. It should be noted that the electronic device may be arranged in any combination of the above, but is not limited thereto. In addition, the electronic device may have a rectangular shape, a round shape, a polygonal shape, a shape having curved edges, or other suitable shapes. The electronic device may comprise an electronic component. An electronic device may have peripheral systems such as a drive system, a control system, a light system, a shelving system, etc. to support the display device, the antenna device, or the splicing device.

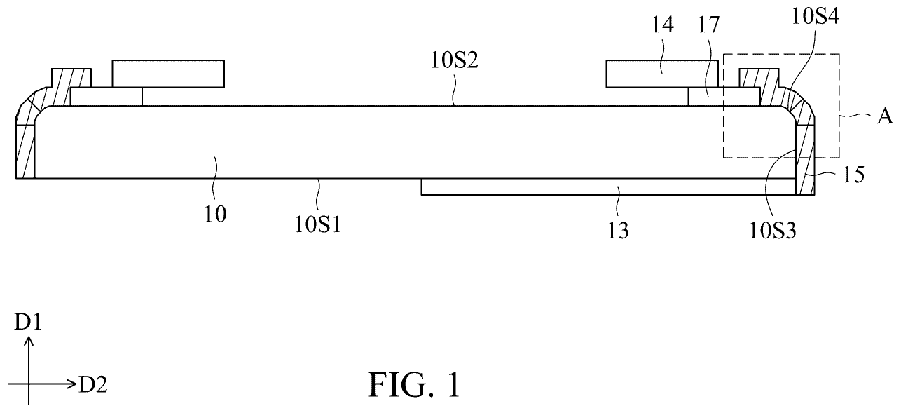

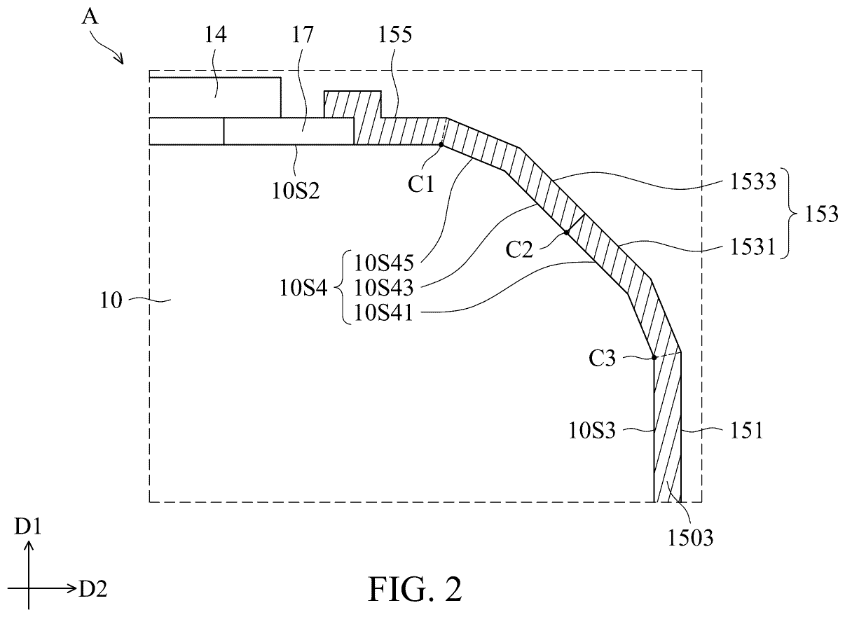

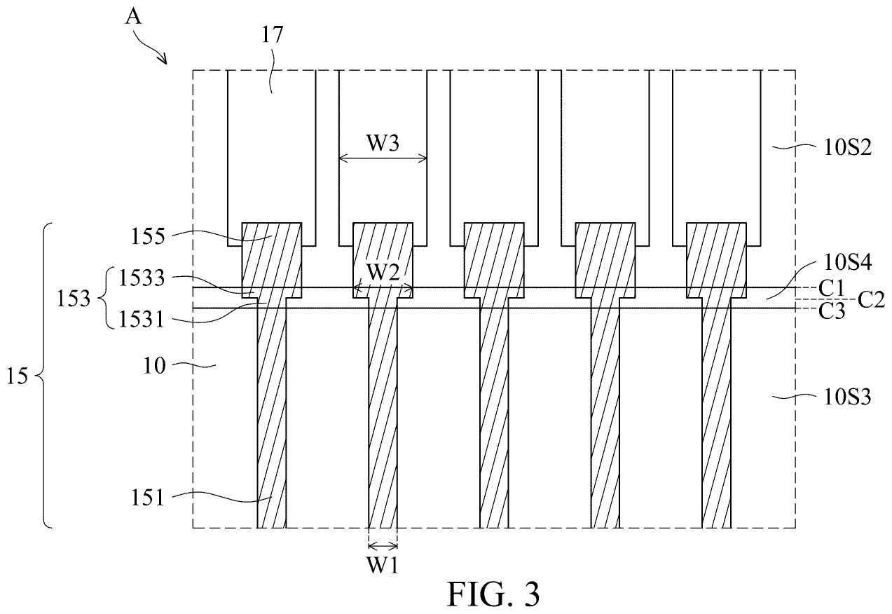

An aspect of the present disclosure provides an electronic device. A structure of the electronic device according to an embodiment of the present disclosure will be described in detail below with reference to FIGS. 1 to 3. FIG. 1 is a cross-sectional schematic view of an electronic device 1 according to an embodiment of the present disclosure. FIG. 2 is an enlarged schematic view of an area A of the electronic device 1 shown in FIG. 1. FIG. 3 is a schematic plan view of the area A shown in FIG. 1.

As shown in FIGS. 1 to 3, the electronic device 1 of the present disclosure includes a first substrate 10 and a first wire 13, a side wire 15, and a second wire 17 disposed on the first substrate 10. The first substrate 10 has a first surface 10S1, a second surface 10S2 opposite the first surface 10S1, a side surface 10S3 between the first surface 10S1 and the second surface 10S2, and a chamfer surface 10S4 between the second surface 10S2 and the side surface 10S3. The first wire 13 is disposed on the first surface 10S1 of the first substrate 10. The second wire 17 is disposed on the second surface 10S2 of the first substrate 10. The side wire 15 is disposed on the side surface 10S3, the chamfer surface 10S4, and the second surface 10S2 of the first substrate 10 and is electrically connected to the first wire 13 and the second wire 17. The side wire 15 has a first portion 151 disposed on the side surface 10S3, a second portion 153 disposed on the chamfer surface 10S4, and a third portion 155 disposed on the second surface 10S2, wherein the width W2 of the second portion 153 of the side wire 15 is less than or equal to the width W3 of the second wire 17.

The first substrate 10 may include a flexible substrate, a rigid substrate, or a combination of the above, but the present disclosure is not limited thereto. In some embodiments, the first substrate 10 may be a translucent substrate or a semi-translucent substrate. According to some embodiments, a material of the first substrate 10 may include a glass, a quartz, a sapphire, a ceramic, a polyimide (PI), a polycarbonate (PC), a polyethylene terephthalate (PET), a polypropylene (PP), other suitable materials, or any combination of the above, but the present disclosure is not limited thereto. In some embodiments, the first substrate 10 may further include a conductive layer, an insulating layer, a dielectric layer, a display media layer, an air layer, a vacuum layer, or any combination of the above, but the present disclosure is not limited thereto.

The first substrate 10 has a first surface 10S1, a second surface 10S2 opposite the first surface 10S1, a side surface 10S3 between the first surface 10S1 and the second surface 10S2, and a chamfer surface 10S4 between the second surface 10S2 and the side surface 10S3. A normal direction D1 of the electronic device 1 is substantially perpendicular to the first surface 10S1 and the second surface 10S2 of the electronic device 1. The normal direction D1 of the electronic device 1 is substantially parallel to the side surface 10S3 of the electronic device 1. The chamfer surface 10S4 connects the second surface 10S2 and the side surface 10S3. In some embodiments, the chamfer surface 10S4 may be an inclined plane with one slope. In some embodiments, the chamfer surface 10S4 may include a plurality of inclined planes with different slopes. For example, in some embodiments, the chamfer surface 10S4 includes a first sub-surface 10S41, a second sub-surface 10S43, and a third sub-surface 10S45. The first sub-surface 10S41 is adjacent to the side surface 10S3, the third sub-surface 10S45 is adjacent to the second surface 10S2, and the second sub-surface 10S43 is between the first sub-surface 10S41 and the third sub-surface 10S45. The first sub-surface 10S41, the second sub-surface 10S43, and the third sub-surface 10S45 have different planar slopes from each other as shown in FIG. 2, but the present disclosure is not limited thereto. The interface between the chamfer surface 10S4 and the second surface 10S2 is defined as the first interface C1 of the first substrate 10, and the interface between the chamfer surface 10S4 and the side surface 10S3 is defined as the second interface C3 of the first substrate 10. A chamfer surface center C2 of the first substrate 10 is between the first interface C1 and the second interface C3, and the distance between the chamfer surface center C2 and the first interface C1 is equal to the distance between the chamfer surface center C2 and the second interface C3.

The first wire 13 may be formed on the first surface 10S1 of the first substrate 10 and extend in a first wire direction. The first wire 13 may include a single layer or a multi-layer structure. The first wire 13 may be formed of a copper, an aluminum, a molybdenum, a tungsten, a gold, a chromium, a nickel, a platinum, a titanium, an iridium, a rhodium, an alloy of the above, any combination of the above, or other metallic materials having good electrical conductivity. The method of forming the first wire 13 may include, but is not limited to, a printing process, an inkjet process, an electroplating process, a chemical plating process, a deposition process, a lithography process, an etching process, or any other commonly used process. The deposition process may include a chemical vapor deposition (CVD) method, a sputtering method, a resistance heating vapor deposition method, an electron beam vapor deposition method, or any other suitable deposition method. In some embodiments of the present disclosure, the chemical vapor deposition method may be a low pressure chemical vapor deposition (LPCVD) method, a low temperature chemical vapor deposition (LTCVD) method, a rapid thermal chemical vapor deposition (RTCVD) method, a plasma enhanced chemical vapor deposition (PECVD) method, an atomic layer deposition (ALD) method, or other commonly used methods, but the present disclosure is not limited thereto. The lithography process includes a photoresist coating (e.g., spin coating) process, a soft baking process, a mask alignment process, an exposure process, a post-exposure baking process, a photoresist developing process, a rinsing process, a drying (e.g., hard baking) process, other suitable processes, or a combination of the above. Alternatively, the lithography process may be performed by, or replaced by, other suitable methods, such as a maskless lithography process, an electron-beam writing process, and an ion-beam writing process. The etching process includes a dry etching process, a wet etching process, or other etching process, but the present disclosure is not limited thereto.

The second wire 17 may be formed on the second surface 10S2 and extend in a second wire direction. The second wire 17 has the width W3 in a direction perpendicular to the second wire direction. The ‘width W3’ of the second wire 17 refers to a maximum width of the second wire 17 in the direction perpendicular to the second wire direction, as shown in FIG. 3. In some embodiments, the first interface C1 of the first substrate 10 is between the boundary of the second wire 17 and the chamfer surface center C2 of the first substrate 10, but the present disclosure is not limited thereto. In some embodiments, the first interface C1 of the first substrate 10 may be flush with the boundary of the second wire 17.

The second wire 17 may include a single layer or a multi-layer structure. The second wire 17 may include a copper, an aluminum, a molybdenum, a tungsten, a gold, a chromium, a nickel, a platinum, a titanium, an iridium, a rhodium, alloys of the above, any combination of the above, or other metallic materials having good conductivity. The material and structure of the second wire 17 may be the same as or different from the material and structure of the first wire 13. The method of forming the second wire 17 may include a printing process, an inkjet process, an electroplating process, a chemical plating process, a deposition process, a lithography process, an etching process, or other commonly used processes. The method of forming the second wire 17 may be the same as or different from the method of forming the first wire 13.

The side wire 15 is formed on the side surface 10S3, the chamfer surface 10S4, and the second surface 10S2 of the first substrate 10 and electrically connects the first wire 13 and the second wire 17. The side wire 15 may include a single layer or a multi-layer structure. In some embodiments, for example, the side wire 15 may include a first conductive layer 1503, but the present disclosure is not limited thereto. In some embodiments, the side wire 15 may further include a second conductive layer disposed on the first conductive layer 1503. The method of forming the side wire 15 may include a printing process, an inkjet process, an electroplating, a sputtering process, a chemical plating, a deposition process, a lithography process, an exposure process, a laser patterning process, an etching process, or other commonly used processes. The method for forming the side wire 15 may be the same or different from the method for forming the second wire 17 and/or the first wire 13. The side wire 15 may include a copper, an aluminum, a molybdenum, a tungsten, a gold, a chromium, a nickel, a platinum, a titanium, an iridium, a rhodium, alloys of the above, any combination of the above, or other metallic materials having good electrical conductivity. The first conductive layer 1503 and the second conductive layer may include the same or different materials from each other. The side wire 15 may include a first portion 151 on the side surface 10S3, a second portion 153 on the chamfer surface 10S4, and a third portion 155 on the second surface 10S2. The first portion 151, the second portion 153, and the third portion 155 of the side wire 15 are arranged along a side wire direction. In the side wire direction, the second portion 153 of the side wire 15 is disposed between the first portion 151 and the third portion 155 and electrically connects the first portion 151 and the third portion 155.

The first portion 151 of the side wire 15 has a width W1 in a direction that is perpendicular to the side wire direction. The second portion 153 of the side wire 15 has a width W2 in a direction that is perpendicular to the side wire direction. The width W2 of the second portion 153 is less than or equal to the width W3 of the second wire 17 and greater than the width W1 of the first portion 151 of the side wire 15. In some embodiments, the difference between the width W2 of the second portion 153 of the side wire 15 and the width W1 of the first portion 151 of the side wire 15 is between 10 μm and 100 μm, but the present disclosure is not limited thereto. In some embodiments, the difference between the width W2 of the second portion 153 of the side wire 15 and the width W1 of the first portion 151 of the side wire 15 is between 15 μm and 95 μm, 20 μm and 80 μm, or 25 μm and 75 μm. In some embodiments, the width of the third portion 155 of the side wire 15 is greater than the width W1 of the first portion 151 of the side wire 15 and less than the width W3 of the second wire 17.

The second portion 153 of the side wire 15 has a first sub-portion 1531 and a second sub-portion 1533 connected to the first sub-portion 1531. The first sub-portion 1531 of the second portion 153 is adjacent to the first portion 151 and the second sub-portion 1533 of the second portion 153 is adjacent to the third portion 155. In some embodiments, the interface between the first sub-portion 1531 and the second sub-portion 1533 overlaps the chamfer surface center C2, but the present disclosure is not limited thereto. In a direction perpendicular to the side wire direction, the width of the second sub-portion 1533 of the side wire 15 is greater than the width of the first sub-portion 1531 of the side wire 15, but the present disclosure is not limited thereto. In some embodiments, the width of the second portion 153 increases incrementally in a direction from the second interface C3 between the chamfer surface 10S4 and the side surface 10S3 towards the first interface C1 between the chamfer surface 10S4 and the second surface 10S2. That is, the width of the first sub-portion 1531 of the side wire 15 increases incrementally in a direction from the second interface C3 between the chamfer surface 10S4 and the side surface 10S3 towards the interface between the first sub-portion 1531 and the second sub-portion 1533. The width of the second sub-portion 1533 of the side wire 15 increases incrementally in a direction from the interface between the first sub-portion 1531 and the second sub-portion 1533 towards the first interface C1 between the chamfer surface 10S4 and the second surface 10S2.

The width of each portion of the side wire 15 described above refers to a maximum width of the portion of the side wire 15 in the direction perpendicular to the side wire direction. For example, the “width W1” of the first portion 151 of the side wire 15 refers to a maximum width of the first portion 151 of the side wire 15 in the direction perpendicular to the side wire direction, and the “width W2” of the second portion 153 of the side wire 15 refers to a maximum width of the second portion 153 of the side wire 15 in the direction perpendicular to the side wire direction, as shown in FIG. 3. By making the first portion 151, the second portion 153, and the third portion 155 of the side wire 15 have the above width design, the side wire of the present disclosure may have a lower contact impedance and/or be less susceptible to fracture or breakage.

In some embodiments, the electronic devices of the present disclosure may include an electronic component 14 disposed on the second surface 10S2 of the first substrate 10. The electronic component 14 may be electrically connected to the second wire 17. Examples of the electronic component 14 may include, but are not limited to, an integrated circuit, a chip on film device (COF), and a flexible printed circuit board (FPC). In some embodiments, a plurality of electronic components 14 may be disposed on the second surface 10S2, and the electronic components 14 may be the same or different from each other.

In some embodiments, the electronic device of the present disclosure may further include an electronic element disposed on the first surface 10S1 of the first substrate 10. The electronic elements may be electrically connected to the first wire 13. Examples of electronic element may include, but are not limited to, passive and active elements, such as capacitors, resistors, inductors, diodes, transistors, and the like. The diodes may include light emitting diodes or photovoltaic diodes. The light emitting diode may include, for example, an organic light emitting diode (OLED), a sub-millimeter light emitting diode (mini LED), a micro LED, or a quantum dot LED, but the present disclosure is not limited thereto. In some embodiments, a plurality of electronic elements may be disposed on the first surface 10S1 and the electronic elements may be the same or different from each other.

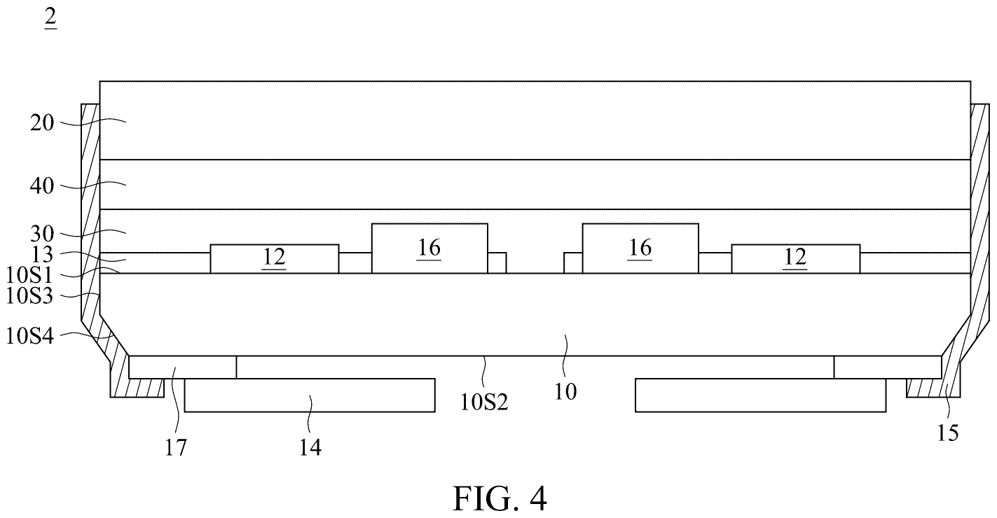

FIG. 4 is a cross-sectional schematic view of an electronic device 2 according to an embodiment of the present disclosure. As shown in FIG. 4, the electronic device 2 of the present disclosure includes a first substrate 10, a second substrate 20 opposite the first substrate 10, a first wire 13, a side wire 15, a second wire 17, a first electronic element 12, an electronic component 14, a second electronic element 16, a first insulating layer 30, and a functional layer 40.

The first substrate 10 has a first surface 10S1, a second surface 10S2 opposite the first surface 10S1, a side surface 10S3 between the first surface 10S1 and the second surface 10S2, and a chamfer surface 10S4 between the second surface 10S2 and the side surface 10S3. Except that the chamfer surface 10S4 is an inclined plane having one slope, the first substrate 10 of the electronic device 2 is substantially the same as the first substrate 10 of the electronic device 1, so it will not be repeated herein. The second substrate 20 is substantially the same as the first substrate 10 except that it does not have the chamfer surface 10S4, so it is not repeated herein.

The first wire 13, the first electronic element 12, the second electronic element 16, the first insulating layer 30, and the functional layer 40 of the electronic device 2 are disposed between the second substrate 20 and the first substrate 10. The first substrate 10 of the electronic device 2 is disposed between the electronic component 14 and the second substrate 20. The second wire 17 of the electronic device 2 is disposed between the electronic component 14 and the first substrate 10. The side wire 15 is disposed on the chamfer surface 10S4, the second surface 10S2, and the side surface 10S3 of the first substrate 10 and extends from the side surface 10S3 of the first substrate 10 to a portion of the side surface of the second substrate 20 as shown in FIG. 4, but the present disclosure is not limited thereto. The first wire 13, the second wire 17, and the electronic component 14 of the electronic device 2 are substantially the same as the first wire 13, the second wire 17, and the electronic component 14 of the electronic device 1, and are therefore not repeated herein. The first electronic element 12 and the second electronic element 16 of the electronic device 2 are substantially the same as the electronic elements described above, and thus are not repeated herein. The first electronic element 12 may be the same as or different from the second electronic element 16. In some embodiments, the first electronic element 12 may be a thin film transistor (TFT) and the second electronic element 16 may be a micro LED.

The first insulating layer 30 of the electronic device 2 may be formed on the first substrate 10 and cover the first wire 13, the first electronic element 12, and the second electronic element 16. The first insulating layer 30 may include a single layer or a multi-layer structure. The first insulating layer 30 may include, but is not limited to, an optical adhesive, such as an OCA (optical clear adhesive) or an OCR (optical clear resin).

The functional layer 40 of the electronic device 2 may be formed on the first insulating layer 30, and the first insulating layer 30 may be disposed between the functional layer 40 and the first substrate 10. The functional layer 40 may include a single layer or a multi-layer structure. In some embodiments, the functional layer 40 may include an optical layer, such as a polarizing layer, a filter layer, a reflective layer, a refractive layer, or any combination thereof, but the present disclosure is not limited thereto. In some embodiments, the functional layer 40 may include a light conversion layer and a color filter layer, and the light conversion layer may include quantum dots, fluorescent powder, phosphor powder, and the like.

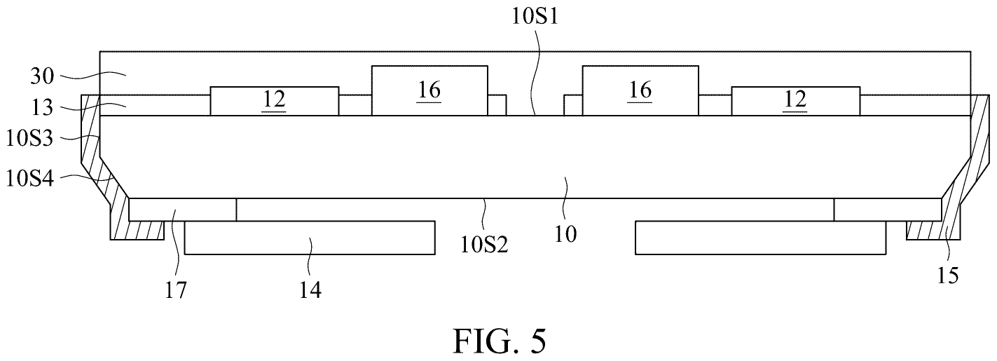

FIG. 5 is a cross-sectional schematic view of an electronic device 3 according to an embodiment of the present disclosure. As shown in FIG. 5, the electronic device 3 of the present disclosure includes a first substrate 10, a first wire 13, a side wire 15, a second wire 17, a first electronic element 12, a second electronic element 16, and a first insulating layer 30. Except for the further inclusion of the first insulating layer 30, the electronic device 3 of the present disclosure is substantially the same as the electronic device 1 and will therefore not be repeated herein.

The side wire 15 of the electronic device having the above structure may have a lower contact impedance and/or be less susceptible to fracture or breakage due to the special width design. Therefore, the electronic device disclosed herein may have better reliability and/or electronic characteristics.

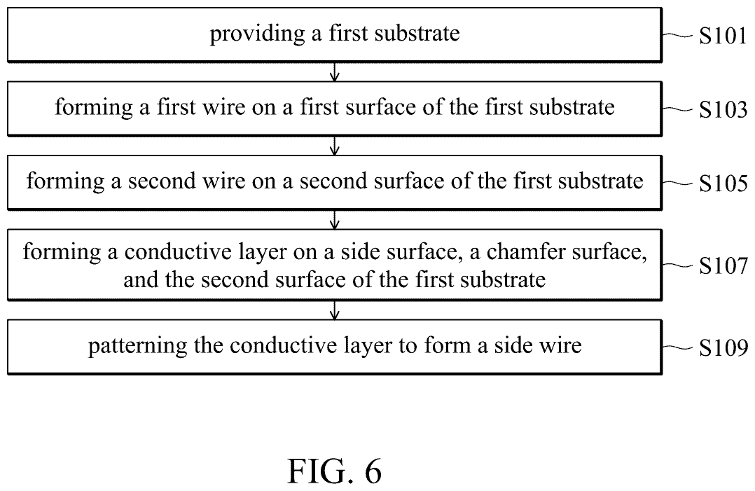

Another aspect of the present disclosure provides a manufacturing method of an electronic device. FIG. 6 is a flowchart of a manufacturing method of an electronic device according to an embodiment of the present disclosure.

As shown in FIG. 6, the manufacturing method of an electronic device of the present disclosure includes: a step S101 of providing a first substrate, wherein the first substrate has a first surface, a second surface opposite the first surface, a side surface between the first surface and the second surface, and a chamfer surface between the second surface and the side surface; a step S103 of forming a first wire on the first surface of the first substrate; a step S105 of forming a second wire on the second surface of the first substrate; a step S107 of forming a conductive layer on the side surface, the chamfer surface, and the second surface of the first substrate; and a step S109 of patterning the conductive layer to form a side wire. The side wire formed in step S109 electrically connects the first wire to the second wire and has a first portion, a second portion, and a third portion. The first portion of the side wire is on the side surface of the first substrate and has a first width W1, the second portion of the side wire is on the chamfer surface and has a second width W2, and the third portion of the side wire is on the second surface of the first substrate. The second wire has a third width W3. The second width W2 of the second portion of the side wire is less than or equal to the third width W3 of the second wire.

In the manufacturing method of the electronic device of the present disclosure, the first substrate 10 provided in step S101 is substantially the same as the first substrate 10 described in the electronic devices 1 to 3 above, and therefore will not be repeated herein.

In the manufacturing method of the electronic device of the present disclosure, the structure, material, and formation method of the first wire 13 and the second wire 17 formed in steps S103 and S105 are substantially the same as those of the first wire 13 and the second wire 17 in the electronic devices 1 to 3, and therefore will not be repeated herein.

In step S107, the conductive layer 15′ is formed on the side surface 10S3, the chamfer surface 10S4, and the second surface 10S2 of the first substrate 10. The conductive layer 15′ may be formed from a copper, an aluminum, a molybdenum, a tungsten, a gold, a chromium, a nickel, a platinum, a titanium, an iridium, a rhodium, alloys of the above, any combination of the above, or other metallic materials having good conductivity by various suitable processes. The conductive layer 15′ may include a single layer or a multi-layer structure. In some embodiments, the conductive layer 15′ may include a dual layer structure including two layers of different materials. In some embodiments, the conductive layer 15′ may include a dual layer structure including two layers of the same or different materials formed by different process parameters. In some embodiments, the conductive layer 15′ may have a dual layer structure including two layers of different materials formed by a sputtering process, but the present disclosure is not limited thereto.

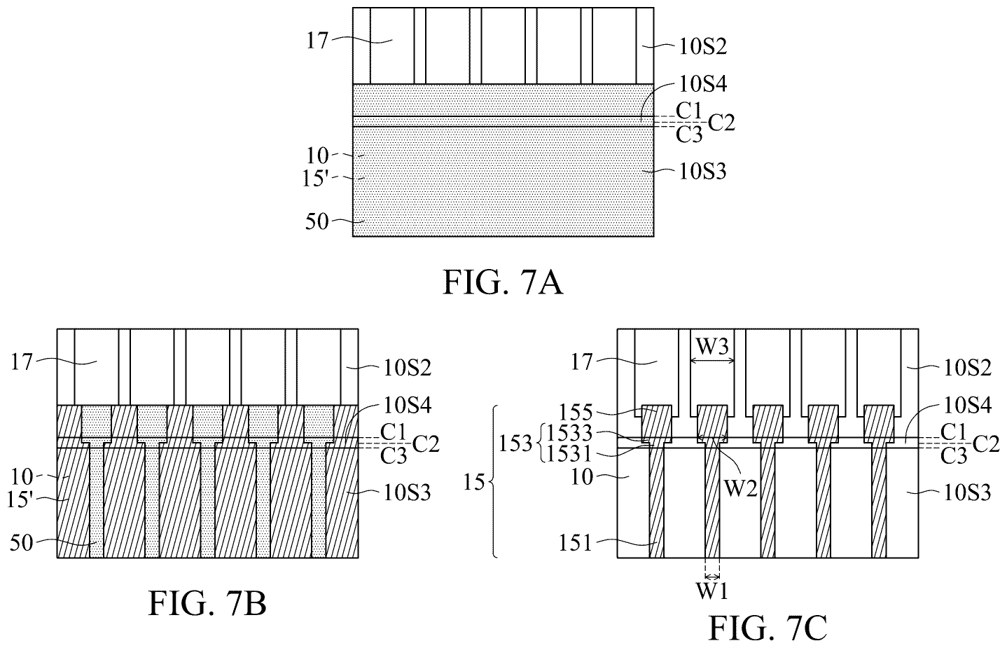

FIGS. 7A to 7C are partial schematic plan views of an electronic device during step S109 in the manufacturing method of the electronic device according to an embodiment of the present disclosure. The steps of patterning the conductive layer in the manufacturing method of the electronic device according to an embodiment of the present disclosure are further described hereinafter with reference to FIG. 6 and FIGS. 7A to 7C.

As shown in FIGS. 7A to 7C, step S109 of patterning the conductive layer 15′ includes forming a barrier layer 50, patterning the barrier layer 50, and etching the conductive layer 15′ by using the barrier layer 50 as a mask. The step of forming the barrier layer 50 includes coating the barrier layer 50 on the conductive layer 15′, wherein the barrier layer 50 completely covers the conductive layer 15′, as shown in FIG. 7A. The method of forming the barrier layer 50 may include, but is not limited to, a screen printing method, a spray coating method, a spin coating method, and/or any combination thereof. The step of patterning the barrier layer 50 may include a photoresist layer formation process, an exposure process, and a developing process. The photoresist layer may include a positive photoresist or a negative photoresist. In the embodiment, the photoresist layer includes a negative photoresist, but the present disclosure is not limited thereto. Examples of the exposure process may include, but are not limited to, a photomask exposure process, a laser direct exposure (LDI) process, or a combination thereof. The barrier layer 50 after the exposure process may be formed into a patterned barrier layer 50 after the developing process, as shown in FIG. 7B. The step of patterning the barrier layer 50 may include one patterning step or multiple patterning steps. In some embodiments, the step of patterning the barrier layer 50 may include a first patterning step and a second patterning step. The first patterning step may include patterning the barrier layer 50 disposed on the side surface 10S3 and patterning a portion of the barrier layer 50 disposed on the chamfer surface 10S4. The second patterning step may include patterning the barrier layer 50 disposed on the second surface 10S2 and patterning another portion of the barrier layer 50 disposed on the chamfer surface 10S4. The patterned barrier layer 50 may be used as a mask to etch the conductive layer 15′ to form the side wire 15, as shown in FIG. 7C. In the embodiment, the barrier layer 50 has better adhesion to form the side wire 15 having good quality.

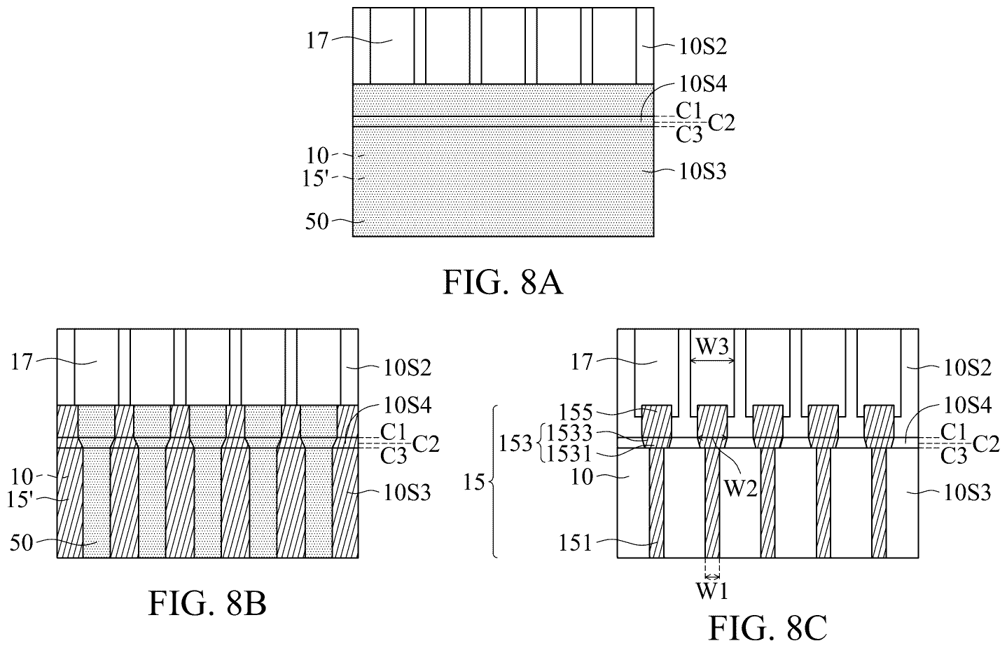

FIGS. 8A to 8C are partial schematic plan views of an electronic device during step S109 in the manufacturing method of the electronic device according to an embodiment of the present disclosure. In the embodiment, except for the step of patterning the barrier layer 50 using a laser patterning process instead of an exposure process and a developing process, the remainder of the processes are substantially the same as the embodiments shown in FIGS. 7A to 7C, and therefore will not be repeated herein. The laser patterning process may include a laser direct imaging process or a laser ablation process, but the present disclosure is not limited thereto. The lasers used in the laser patterning process may be UV, DUV, or green light lasers, but the present disclosure is not limited thereto. The use of lower frequency lasers in the laser patterning process may reduce thermal damage during the process and/or improve the adhesion of the barrier layer 50 to form the side wire 15 having good quality.

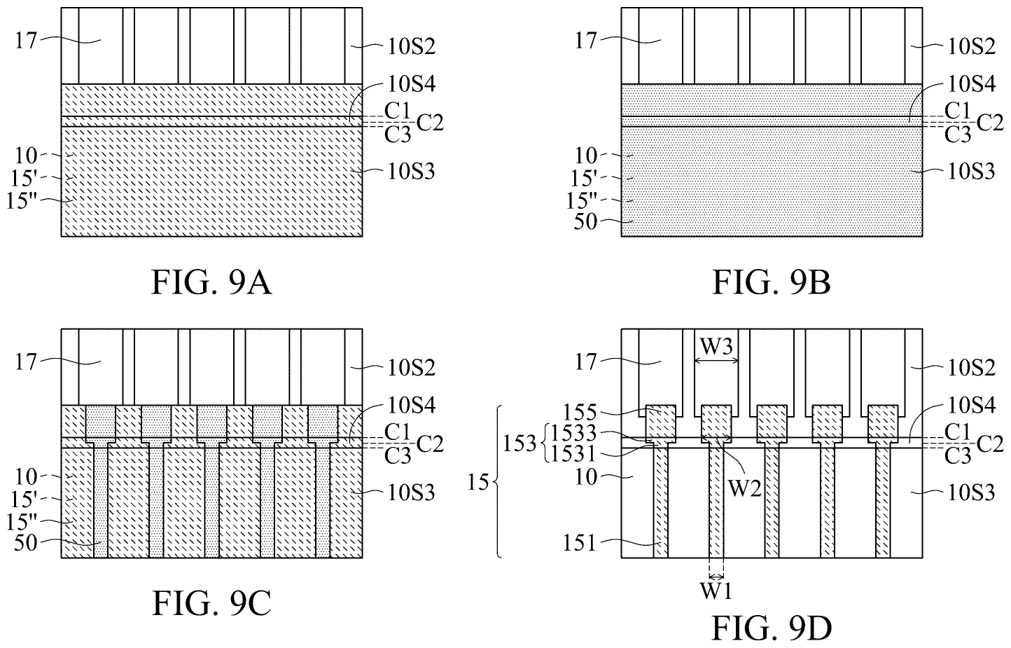

FIGS. 9A to 9D are partial schematic plan views of an electronic device during step S109 in the manufacturing method of the electronic device according to an embodiment of the present disclosure. In the embodiment, except for the formation of an additional conductive layer 15″ on the conductive layer 15′, the remainder of the process is substantially the same as that of the embodiments shown in FIGS. 7A to 7C and will therefore not be repeated herein. In some embodiments, process parameters for forming the additional conductive layer 15″ may be different from process parameters for forming the conductive layer 15′. The additional conductive layer 15″ may adjust the quality of the subsequently formed side wire 15, or improve a process margin of the side wire 15. In addition, the conductive layer 15′ may be cleaned before the step of forming the additional conductive layer 15″ to remove foreign matter attached to the conductive layer 15′, thereby improving the yield of the electronic device.

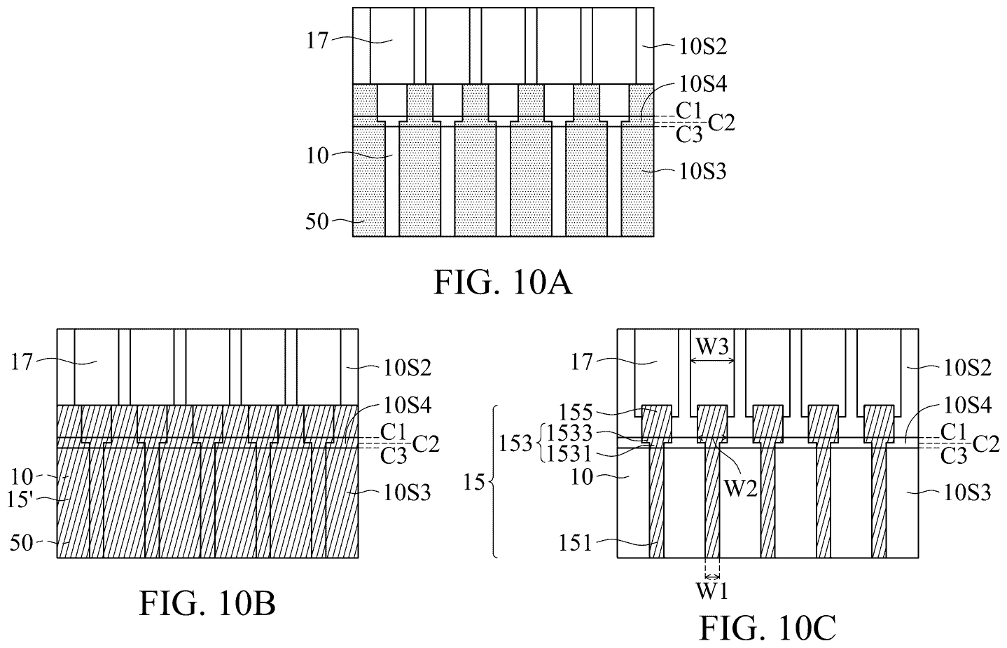

FIGS. 10A to 10C are partial schematic plan views of an electronic device during steps of patterning the conductive layer 15′ in the manufacturing method of the electronic device according to an embodiment of the present disclosure.

As shown in FIGS. 10A to 10C, the steps of patterning the conductive layer 15′ include forming the barrier layer 50 on the side surface 10S3 and the chamfer surface 10S4 of the first substrate 10, patterning the barrier layer 50, forming the conductive layer 15′ on the patterned barrier layer 50, and patterning the conductive layer 15′. The step of forming the barrier layer 50 includes coating the barrier layer 50 on the first substrate 10, wherein the barrier layer 50 completely covers the first substrate 10. The method of forming the barrier layer 50 may include, but is not limited to, a screen printing method, a spray coating method, a spin coating method, and/or any combination thereof. The steps for patterning the barrier layer 50 may include a photoresist layer formation process, an exposure process, and a developing process. The barrier layer 50 may include a photoresist layer. The photoresist layer may comprise a positive photoresist or a negative photoresist. In the embodiment, the photoresist layer includes a positive photoresist, but the present disclosure is not limited thereto. The patterned barrier layer 50 may include an exposure process and a developing process. Examples of the exposure process may include, but are not limited to, a photomask exposure process, a laser direct exposure (LDI) process, or a combination thereof. The photoresist layer after the exposure process may form a patterned barrier layer 50 after the developing process. The patterned barrier layer 50 is formed on the first substrate 10 and exposes the first substrate 10, as shown in FIG. 10A. The conductive layer 15′ is formed on the patterned barrier layer 50 and covers the barrier layer 50 and the first substrate 10, as shown in FIG. 10B. Finally, the barrier layer 50 is removed to pattern the conductive layer 15′ and form the side wire 15 as shown in FIG. 10C. In the embodiment, the barrier layer 50 having a better adhesion can form the side wire 15 having good quality and/or the side wire 15 can adhere well to the first substrate 10 to improve the reliability of the electronic device comprising it.

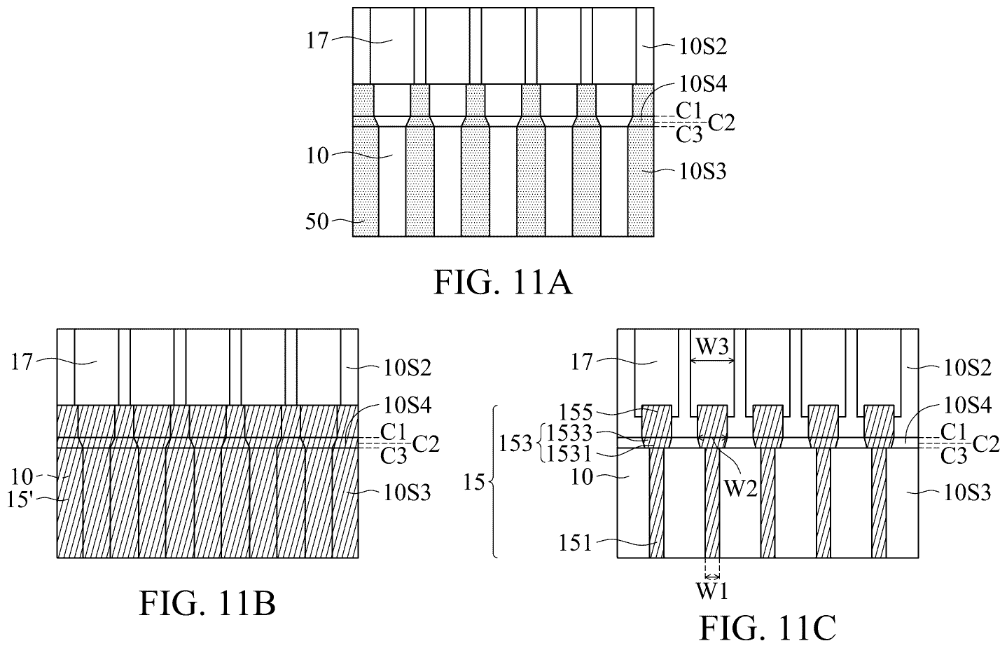

FIGS. 11A to 11C are partial schematic plan views of an electronic device during steps of patterning the conductive layer 15′ in the manufacturing method of the electronic device according to an embodiment of the present disclosure. In the embodiment, except for the step of patterning the barrier layer 50 using a laser patterning process instead of an exposure process and a developing process, the remainder of the processes are substantially the same as the embodiments shown in FIGS. 10A to 10C, and therefore will not be repeated herein. The laser patterning process may include laser direct imaging or laser ablation, but the present disclosure is not limited thereto. The lasers used in the laser patterning process may be UV, DUV, or green light lasers, but the present disclosure is not limited thereto. In the embodiment, the barrier layer 50 having a better adhesion can form the side wire 15 having good quality and/or the side wire 15 can adhere well to the first substrate 10 to improve the reliability of the electronic device comprising it. Further, the use of lower frequency lasers in the laser patterning process may reduce thermal damage during the process and/or improve the adhesion of the barrier layer 50 to form the side wire 15 having good quality.

The side wire 15 formed in each of the embodiments above has a first portion 151 on the side surface 10S3 of the first substrate 10, a second portion 153 on the chamfer surface 10S4 of the first substrate 10, and a third portion 155 on the second surface 10S2 of the first substrate 10. The second portion 153 of the side wire 15 has a second width W2, and the first portion 151 of the side wire 15 has a first width W1 as shown in FIGS. 7C to 11C. In some embodiments, the second width W2 of the second portion 153 of the side wire 15 is less than or equal to the third width W3 of the second wire 17, and the second width W2 of the second portion 153 of the side wire 15 is greater than the first width W1 of the first portion 151 of the side wire 15.

In some embodiments, the second portion 153 of the side wire 15 may include a first sub-portion 1531 and a second sub-portion 1533 connected to the first sub-portion 1531. The first sub-portion 1531 is adjacent to the first portion 151 and the second sub-portion 1533 is adjacent to the third portion 155. The maximum width of the first sub-portion 1531 is different from the maximum width of the second sub-portion 1533. The maximum width herein refers to a maximum width of the first sub-portion 1531 and the second sub-portion 1533 in a direction perpendicular to a direction connecting the first sub-portion 1531 and the second sub-portion 1533. In some embodiments, the width of the first sub-portion 1531 increases incrementally in a direction from the first portion 151 towards the second sub-portion 1533 and the width of the second sub-portion 1533 increases incrementally in a direction from the first sub-portion 1531 towards the third portion 155 as shown in FIGS. 8C and 11C. In some embodiments, the difference in width between the second portion 153 of the side wire 15 and the first portion 151 of the side wire 15 is between 10 μm and 100 μm, but the present disclosure is not limited thereto. In some embodiments, the difference in width between the second portion 153 of the side wire 15 and the first portion 151 of the side wire 15 is between 15 μm and 95 μm, 20 μm and 80 μm, or 25 μm and 75 μm.

The side wire 15 of the electronic device having the aforementioned structure may have a lower contact impedance and/or be 1 less susceptible to fracture or breakage due to the special width design. Therefore, the electronic device disclosed herein may have better reliability and/or electronic characteristics.

The foregoing outlines features of several embodiments so that those skilled in the art may better understand the aspects of the present disclosure. The features of the various embodiments can be mixed and matched at will as long as they do not violate the spirit of the invention or conflict with each other. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various combinations, changes, substitutions, and modifications herein without departing from the spirit and scope of the present disclosure.

What is claimed is:

1. An electronic device, comprising:
a first substrate having a first surface, a second surface opposite the first surface, a side surface between the first surface and the second surface, and a chamfer surface between the second surface and the side surface;
a first wire disposed on the first surface;
a side wire disposed on the side surface, the chamfer surface and the second surface and electrically connected to the first wire, wherein the side wire has a first portion on the side surface, a second portion on the chamfer surface, and a third portion on the second surface; and
a second wire disposed on the second surface and electrically connected to the side wire,
wherein a width W2 of the second portion is less than or equal to a width W3 of the second wire.

2. The electronic device as claimed in claim 1, wherein the width W2 of the second portion is greater than a width W1 of the first portion.

3. The electronic device as claimed in claim 1, wherein the second portion of the side wire on the chamfer surface has a first sub-portion and a second sub-portion, wherein the first sub-portion is adjacent to the first portion, the second sub-portion is adjacent to the third portion, and a width of the second sub-portion is greater than a width of the first sub-portion.

4. The electronic device as claimed in claim 3, wherein the chamfer surface comprises a first sub-surface, a second sub-surface, and a third sub-surface, wherein the first sub-surface is adjacent to the side surface, the third sub-surface is adjacent to the second surface, the second sub-surface is between the first sub-surface and the third sub-surface, and an interface between the first sub-portion and the second sub-portion is on the second sub-surface.

5. The electronic device as claimed in claim 1, wherein the width of the second sub-portion of the side wire on the chamfer surface increases incrementally in a direction from an interface between the side surface and the chamfer surface towards an interface between the chamfer surface and the second surface.

6. The electronic device as claimed in claim 1, wherein a difference in width between the second portion and the first portion is between 10 μm and 100 μm.

7. The electronic device as claimed in claim 1, wherein a width of the third portion is greater than a width W1 of the first portion and less than the width W3 of the second wire.

8. The electronic device as claimed in claim 1, wherein the side wire comprises a first conductive layer and a second conductive layer disposed on the first conductive layer.

9. The electronic device as claimed in claim 8, wherein the first conductive layer and the second conductive layer comprise the same materials.

10. The electronic device as claimed in claim 8, wherein the first conductive layer and the second conductive layer comprise different materials.

11. The electronic device as claimed in claim 1, further comprising an electronic element disposed on the first surface and electrically connected to the first wire.

12. A manufacturing method of an electronic device, comprising:
providing a first substrate, the first substrate having a first surface, a second surface opposite the first surface, a side surface between the first surface and the second surface, and a chamfer surface between the second surface and the side surface;
forming a first wire on the first surface;
forming a second wire on the second surface;
forming a conductive layer on the side surface, the chamfer surface and the second surface; and
patterning the conductive layer to form a side wire, wherein the side wire is electrically connected to the first wire and the second wire,
wherein a first portion of the side wire on the side surface has a first width W1, a second portion of the side wire on the chamfer surface has a second width W2, the second wire has a third width W3, and the second width W2 is less than or equal to the third width W3.

13. The manufacturing method of the electronic device as claimed in claim 12,
wherein the width W2 is greater than the width W1.

14. The manufacturing method of the electronic device as claimed in claim 12,
wherein the step of patterning the conductive layer comprises:
forming a barrier layer on the conductive layer;
patterning the barrier layer; and
etching the conductive layer by using the barrier layer as a mask.

15. The manufacturing method of the electronic device as claimed in claim 14, wherein a method for patterning the barrier layer is laser direct imaging.

16. The manufacturing method of the electronic device as claimed in claim 14, wherein a method for patterning the barrier layer is laser ablation.

17. The manufacturing method of the electronic device as claimed in claim 14, wherein the step of patterning the barrier layer comprises:
patterning a portion of the barrier layer, wherein the portion is disposed on the side surface and a portion of the chamfer surface; and
patterning another portion of the barrier layer, wherein the another portion is disposed on the second surface and another portion of the chamfer surface.

18. The manufacturing method of the electronic device as claimed in claim 12, wherein before the step of forming the conductive layer on the side surface, the chamfer surface and the second surface, the method further comprises:
forming a barrier layer on the side surface, the chamfer surface and the second surface; and
patterning the barrier layer.

19. The manufacturing method of the electronic device as claimed in claim 12, wherein the side wire comprises a first conductive layer and a second conductive layer disposed on the first conductive layer.

20. The manufacturing method of the electronic device as claimed in claim 12, wherein a difference in width between the second portion and the first portion is between 10 μm and 100 μm.
